(19) United States
(12) Patent Application Publication
(10) Pub. No.: US 2026/0185584 A1
(43) Pub. Date: Jul. 2, 2026

(54) Protective Impact Cover for Input to Active Suspension Shock Absorber

(71) Applicant: N10Z Performance Shocks LLC, Johnson City, TN (US)

(72) Inventor: Peter Russell, Johnson City, TN (US)

(73) Assignee: N10Z Performance Shocks LLC, Johnson City, TN (US)

(21) Appl. No.: 19/433,700

(22) Filed: Dec. 26, 2025

Related U.S. Application Data
(60) Provisional application No. 63/739,669, filed on Dec. 29, 2024.

(51) Int. Cl. F16F 9/38; B60G 99/00; H05K 5/03

(52) U.S. Cl. CPC F16F 9/38; H05K 5/03; B60G 99/00; F16F 2230/0023

(57) ABSTRACT

A protective shield is provided for a shock absorber valve. The protective shield includes an annular cap having a base, a circumferential body, a plate, and an aperture provided in the cap for coupling an electrical line and connector with a complementary connector provided in shielded relation within the cap. The clamp member is provided along the base of the cap and configured to rigidly affix the cap onto a shock absorber valve mount body.

### CROSS REFERENCE TO RELATED APPLICATIONS

This patent application claims the benefit of U.S. Provisional Patent Application Ser. No. 63/739,669, filed Dec. 29, 2024, entitled “Protective Impact Cover for Input to Active Suspension Shock Absorber”, the disclosures of which are incorporated herein by reference.

### TECHNICAL FIELD

The technical field is impact, heat transfer and energy absorbing shields and covers for input and/or control components of a shock absorber or damper. More particularly, the technical field is impact, thermal, and energy dissipating shields for electrical/electronic shock absorber control units and connectors for active control suspension systems.

### BACKGROUND OF THE DISCLOSURE

Remote control components on shock absorber assemblies are provided in locations that need impact protection of control components of an active suspension system, such as on a shock absorber. The mass of shock absorber systems places such control components at risk of damage during removal, repair and maintenance. Simple snap-on plastic caps, similar to caps on cans of spray paint, have been used to cover such components but they are incapable of protecting the components from significant damage from impacts due to falling or dropped shock absorber systems, or impacts with external objects. Accordingly, improvements are needed to protect control components, including solenoid assemblies and connectors and other control components for active suspension systems and/or shock absorber assemblies.

### SUMMARY OF THE INVENTION

A protective impact cover is provided for a remote control component on a shock absorber assembly.

According to one aspect, a protective shield is provided for a shock absorber valve. The protective shield includes an annular cap having a base, a circumferential body, a plate, and an aperture provided in the cap for coupling an electrical line and connector with a complementary connector provided in shielded relation within the cap. The clamp member is provided along the base of the cap and configured to rigidly affix the cap onto a shock absorber valve mount body.

According to another aspect, a protective impact cover for a shock absorber control component is provided. The protective impact cover, includes a circumferentially encasing impact-resistant body component, a mounting collar, and a clamp member. The circumferentially encasing impact-resistant body component has an aperture for accessing a control component housed in the body component to connect a remote control component with the control component, a top end, and an open bottom end. The mounting collar is provided along the open bottom end of the body component. The clamp member is provided on the mounting collar configured to rigidly affix the body component about a housed control component with sufficient impact load capacity to protect the control component from external impact loads generated by a shock absorber mass impinging on an impact surface.

### BRIEF DESCRIPTION OF THE DRAWINGS

FIG. 1 is a perspective view of a shock absorber assembly having an exposed cable connector for an electronic control solenoid assembly in an active suspension system.

FIG. 2 is a perspective view of a shock absorber assembly having a protective impact cover for a cable connector for an electronic control solenoid assembly in an active suspension system according to one embodiment.

FIG. 3 is a perspective view from above of the protective impact cover of FIG. 2.

FIG. 4 is a perspective view from below of the protective impact cover of FIG. 3.

FIG. 5 is a perspective view from further below and rotated axially of the protective impact cover of FIG. 4.

FIG. 6 is a plan view from above of the protective impact cap of FIGS. 2-5.

FIG. 7 is vertical sectional view taken along line 7-7 of FIG. 6.

FIG. 8 is vertical sectional view taken along line 8-8 of FIG. 6 further showing a solenoid and connector in phantom inside of the protective impact cover.

FIG. 9 is a perspective view from above of one alternative protective impact cover having enhanced thermal cooling and energy absorbing characteristics over that depicted in FIG. 3.

### DETAILED DESCRIPTION OF THE EMBODIMENTS

This disclosure is submitted in furtherance of the constitutional purposes of the U.S. Patent Laws “to promote the progress of science and useful arts” (Article 1, Section 8).

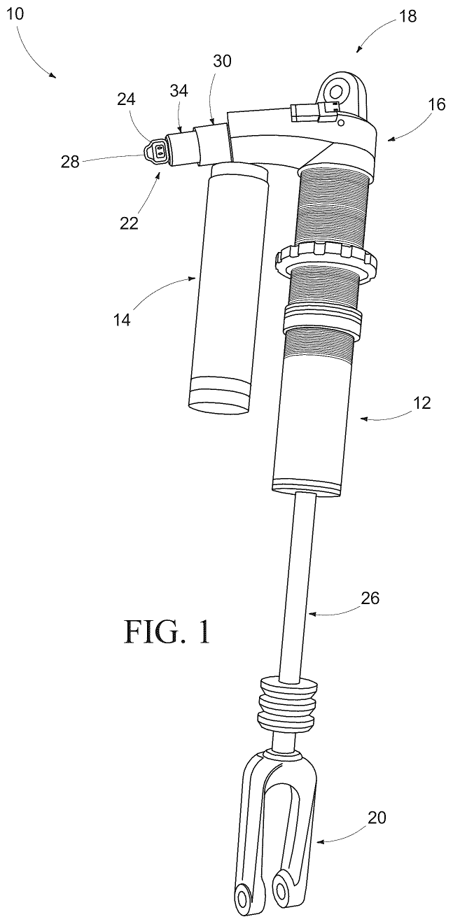

FIG. 1 is a perspective view of a shock absorber assembly 10 having an exposed active suspension control cable connector 24 on a control solenoid assembly 22 for an electronic control solenoid steel tube 34 in an active suspension system of shock absorber assembly 10. Solenoid assembly 22 is affixed onto end cap 16 along a solenoid clamp collar 34 with a solenoid retaining collar 30 that connects onto end cap 16. A plug connector retainer bridge 28 is integrally formed on plastic plug connector housing 24 which is prone to break when storing, moving, shipping and working on a shock absorber assembly 10 resulting from impacts such as the shock absorber assembly 10 tipping over and impacting with a concrete shop floor. Other impacts are also envisioned. Assembly 10 can be bulky and heavy from the combination of a reservoir tube 14, shock absorber tube 12, an upper bridge housing end cap 16, an eyelet 18, piston shaft 26, and clevis 20, and is further filled with a working shock absorber fluid.

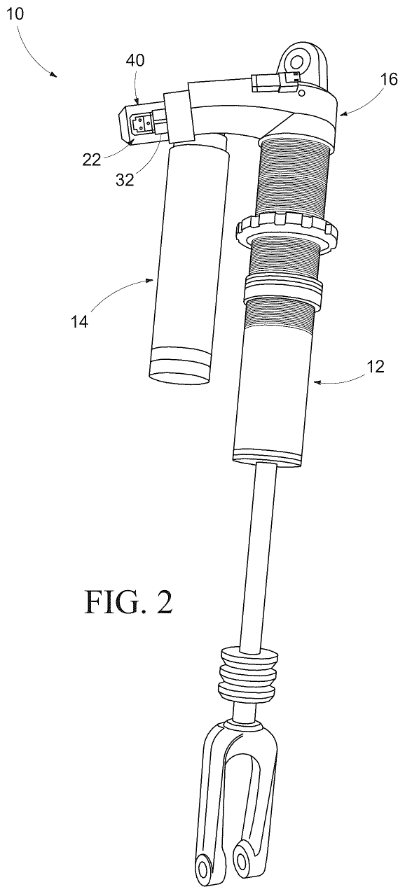

FIG. 2 is a perspective view of a shock absorber assembly 10 having a protective impact cover, or shield 40 for a plastic plug connector housing 24 (see FIG. 1) affixed onto a solenoid assembly 22 for an electronic control solenoid assembly in an active suspension system with a clamp collar 32 according to one embodiment. Upper bridge housing end cap 16 supports shock absorber tube 12 (containing a mid-valve piston) and reservoir tube 14.

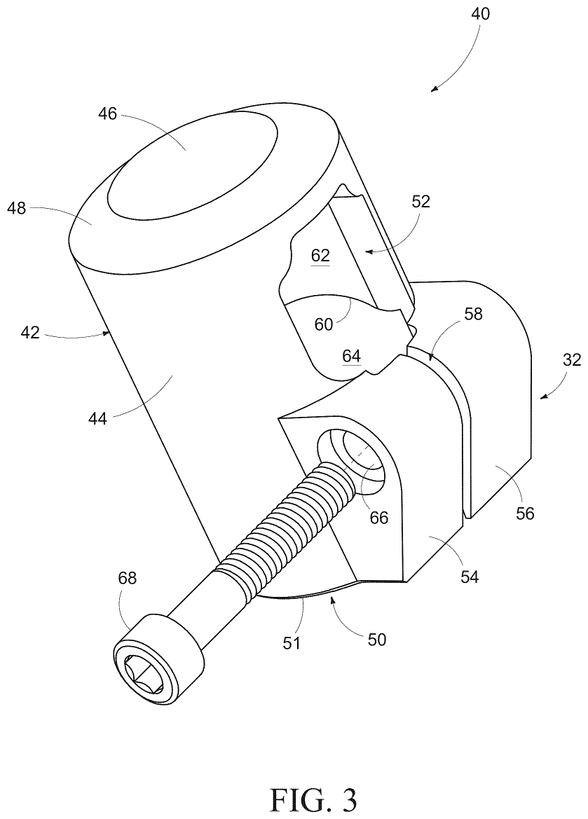

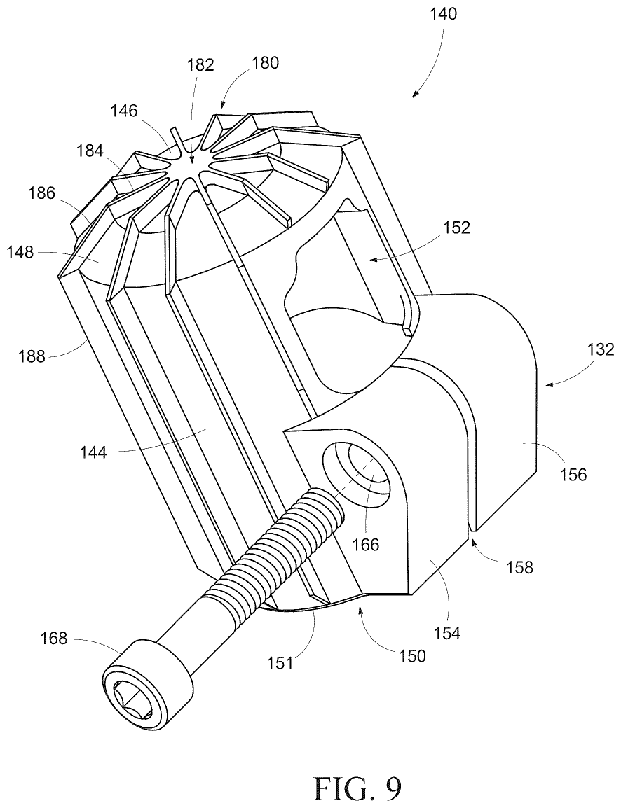

FIG. 3 is a perspective view from above of the protective impact cover 40 of FIG. 2. In operation, protective impact cover 40 shields solenoid assembly 22 and related connector and plastic components from impact damage in the event of an impact or a fall/drop of shock absorber assembly 10. In one case, a clamp assembly 32 and a protective enclosure, or housing 42 of protective impact cover 40 are formed from an aluminum alloy, such as 6061 or 7075 aluminum alloy. However, other materials sufficient to protect against impact damage to housed internal components can be used such as steel, composite, structurally rigid plastics, and other alloy materials. Further additionally or optionally, such components can be made with the addition of impact energy absorbing deformation (elastic or plastic) features, such as provision of aluminum fins (which bend on impact) shown in cover 140 (see FIG. 9) or by a resilient elastic or plastic deformation layer provided about an outer surface of cover 40 or 140. In addition, fins on cover 140 (see FIG. 9) provide an increase in thermal dissipation that helps draw heat from shock absorber components housed and protected within housing 40 or 140. Cap 40 provides an increased outer surface area on enclosure 42 over the inside surface area which to a lesser extent increases thermal dissipation of heat inside of cover 40.

As shown in FIG. 3, enclosure 42 comprises a cylindrical top end wall 46, a frustrum, or beveled circumferential wall portion 48 contiguous with wall 46 to cooperatively form an end plate, and a cylindrical wall 44. A pair of clamp members are integrally formed with wall 44 along a bottom open end 50. An access port, or window 52 is provided in wall 44 to enable access to insert and mate a complementary connector with a plug connector on solenoid assembly 22 (see FIG. 2). A circumferential shelf 60 is formed between cylindrical inner wall 62 and cylindrical inner wall, or clamp surface 64. Shelf 60 seats and structurally affixes against a complementary steel shoulder on clamp collar 34 (see FIG. 1) to provide an impact resistant connection that protects components within cover 40.

As shown in FIG. 3, clamp assembly 32 of cover 40 includes a pair of clamp members, or flanges 54 and 56 integrally formed along a bottom portion of wall 44 having a slot, or gap 58 provided there between. A recessed threaded fastener bore 66 is sized to extend through clamp members 54 and 56 is threads into complementary threaded portion 70 of bore 66 while a threaded fastener, or cap screw 66 is engaged into threaded portion 70, causing gap 58 to close and rigidly and securely engaging clamp surface 64 about clamp collar 34 (see FIG. 1). Optionally, clamp assembly 32 can be affixed about wall 44 as a separate component to close a gap in wall 44 that grips and secures cover, or body component 40 onto a support component such as a clamp collar.

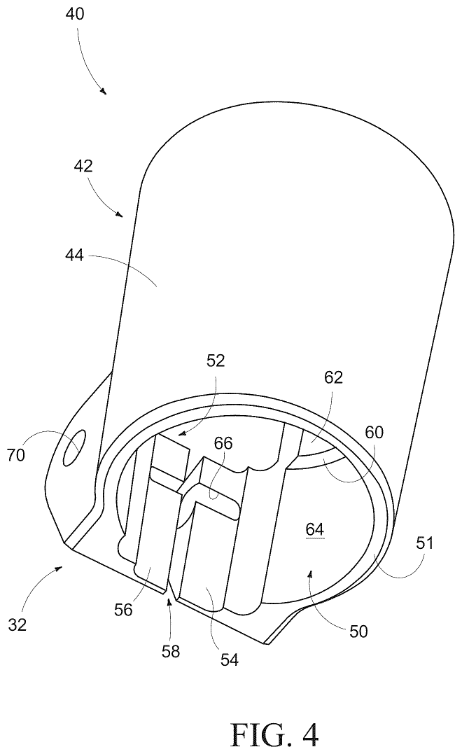

FIG. 4 is a perspective view from below of the protective impact cover 40 of FIG. 3. More particularly, housing 42 is shown with an open bottom end, or opening 50 along a bottom portion of wall 44 in the region of clamp assembly 32 at a base 51. Clamp collar 34 (see FIG. 1) is inserted into opening 50 and clamp assembly 32 is tightened to secure and lock cover 40 over a solenoid assembly and plug connector (not shown) sufficient to be retained under impact loading generated from hitting or dropping a shock assembly. Clamp surface 64 is shown beneath window 52 and cylindrical shoulder 60 is provided between inner surfaces 62 and 64. In assembly, cylindrical shoulder 60 seats against and end of steel clamp collar 30 (see FIG. 1). Fastener bore 66 extends through clamp member 54 and aligns with threaded portion 70 in clamp member 56 while slot 58 reduces or closes as a threaded fastener is tightened there between.

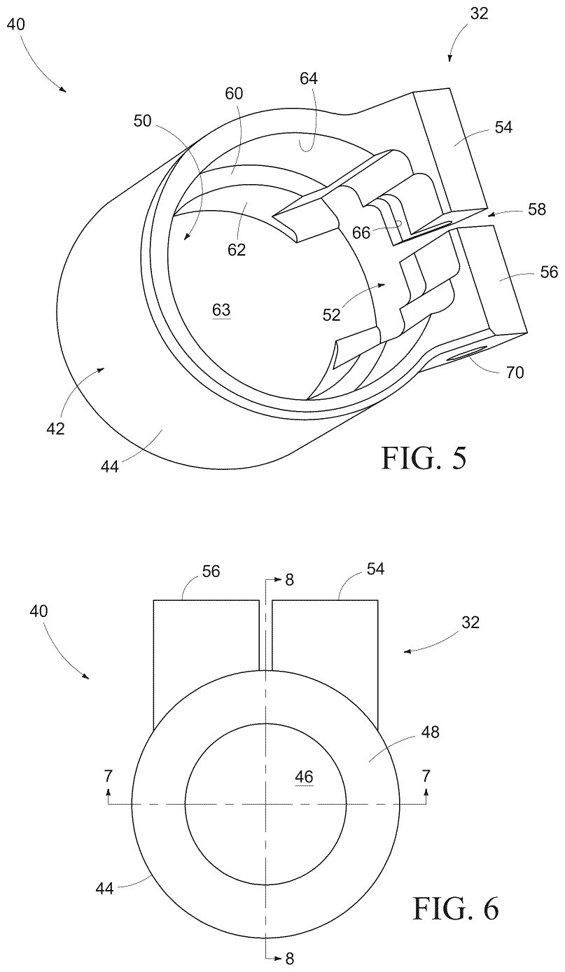

FIG. 5 is a perspective view from further below and rotated axially of the protective impact cover 40 of FIG. 4 showing in further detail internal components of housing 42 and clamp collar assembly 32. More particularly, bore 66 on clamp member 54, threaded bore 70 on clamp member 56, spaced apart by slot 58 are shown below window 52. When secured together with a fastener, wall 44 flexes as members 54 and 56 are drawn together en-smalling a diameter of clamp surface 64 and closing gap 58. Cylindrical shoulder, or abutment 60 is shown transitioning from smaller diameter wall 62 to larger diameter wall 64. Inner ceiling, or wall 63 is shown viewed through bottom opening 50 in protective impact cover 40.

FIG. 6 is a plan view from above of the protective impact cover, or cap 40 of FIGS. 2-5 showing in plan view clamp assembly 32 including clamp members, or legs 54 and 56 integrally formed into cylindrical wall 44. Top wall portion 46 transitions to a sloped circumferential frustrum, or wall 48 into vertical cylindrical wall portion 44. Such surface 48 minimizes sharp edges that might otherwise snag items during an impact event and are more likely to impart an impact surface that deflects impact energy, thereby reducing peak impact forces to cover 40 (and affixed shock components).

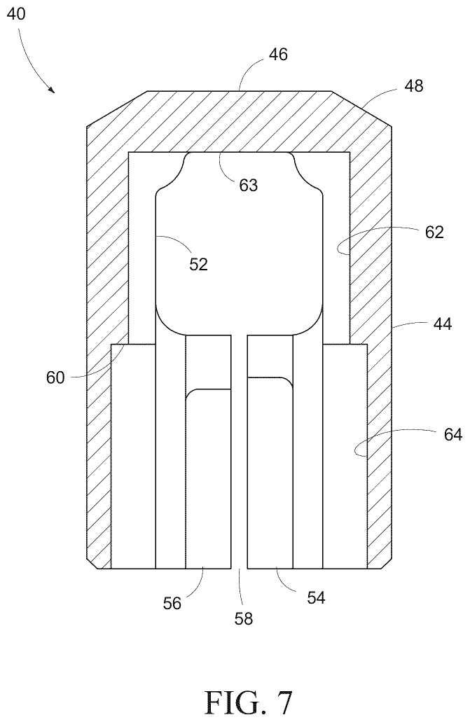

FIG. 7 is vertical sectional view taken along line 7-7 of FIG. 6 showing details of cover 40. More particularly, walls 44, 46 and 48 provide a protective outer impact surface for cover 40. Inner wall, or clamp portion 64 and cylindrical shelf 60 provide rigid affixation surface to clamping onto a clamp collar 34 (see FIG. 1) sufficient to prevent damage from impact events with external surfaces. Window 52, inner wall portion 62 and inner ceiling, or wall portion 63 are ideally spaced apart from any solenoid components or connectors housed in cover 40 to prevent shock transmission to such components through direct contact with cover 40. Slot, or gap 58 is shown in an unloaded, or unclamped condition between clamp members 54 and 56.

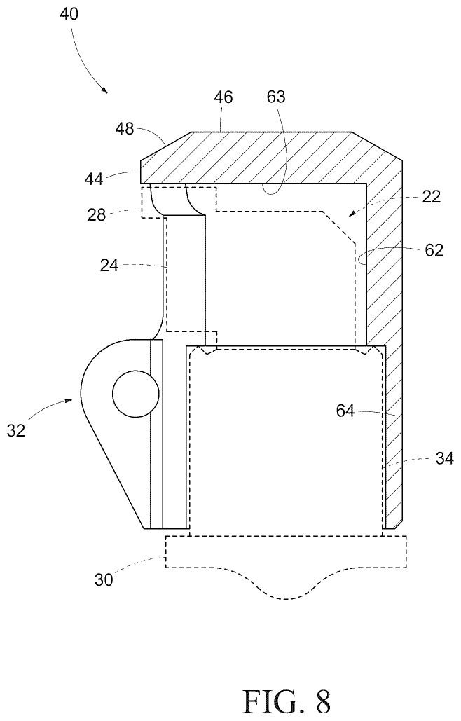

FIG. 8 is vertical sectional view taken along line 8-8 of FIG. 6 further showing a solenoid assembly 22 including solenoid tube 34 and connector 24 in phantom inside of the protective impact cover 40. A plastic plug connector retainer bridge 28 extends atop plastic plug connector housing 24. External surfaces 44 and 48 cooperate with a radially outwardly extending flange of clamp assembly 32 to protect bridge 28 and connector 24 from impact with external objects, such as a shop floor when a shock absorber assembly falls over while leaning on a work bench table. Top 46 also protects components of solenoid assembly 22. Optionally, housing 24 and bridge 28 can be sized smaller relative to cover 40 so they are recessed and provide even further impact protection to housed internal components. Plug connector housing 22 is spaced from walls 62 and 63 while steel solenoid tube 34 is affixed to cover 40 via clamp assembly 32, adjacent and next to solenoid retaining collar 30.

FIG. 9 is a perspective view from above of one alternative protective impact cover 140 having enhanced thermal cooling and energy absorbing characteristics over that depicted in FIG. 3. More particularly, cover 140 includes an array 180 of integrally formed thin aluminum alloy cooling fins 184, 186 and 188 extending outwardly from outer wall 144, frustrum 148 and top wall 146. Fins 182, 184, and 186 radiate outwardly from a common central hub 182. Fins 182, 184 and 186 increase outer surface area of surface 144 which increase heat transfer away from cover 140 to a surrounding atmosphere. Additionally, fins 182, 184 and 186 are formed from aluminum alloy thin enough to deform under impact with an external object so as to provide shock load mitigation and energy absorption from such impacts, thereby further protecting components affixed within cover 140.

As shown in FIG. 9, clamp assembly 132 includes fastener, or cap screw 168, bore 166, clamp members 154 and 156, and slot 158. Clamp assembly is provided adjacent and above of bottom opening 150 above a base 151 while window 152 enables connection access between a connector inside of cover 140 and an external control connection. Such a connection is envisioned as an electrical and/or electronic connector assembly, but could be a mechanical control connection, a hydraulic connection, or other mechanical linkage system used to control an exposed active suspension control connector or device on a control system for an active suspension system of shock absorber assembly.

The terms “a”, “an”, and “the” as used in the claims herein are used in conformance with long-standing claim drafting practice and not in a limiting way. Unless specifically set forth herein, the terms “a”, “an”, and “the” are not limited to one of such elements, but instead mean “at least one”.

What is claimed is:

1. A protective impact cover for a shock absorber valve, comprising:
an annular cover having a base, a circumferential body, an end plate, and an aperture provided in the cover for coupling an electrical line and connector with a complementary connector provided in shielded relation within the cover; and
a clamp member provided along the base of the cover and configured to rigidly affix the cover onto a shock absorber valve mount body.

2. A protective impact cover for a shock absorber control component, comprising:
a circumferentially encasing impact-resistant body component having an aperture for accessing a control component housed in the body component to connect a remote control component with the control component, a top end, and an open bottom end;
a mounting collar provided along the open bottom end of the body component; and
a clamp member provided on the mounting collar configured to rigidly affix the body component about a housed control component with sufficient impact load capacity to protect the control component from external impact loads generated by a shock absorber mass impinging on an impact surface.
